(19) United States
(12) Patent Application Publication
(10) Pub. No.: US 2009/0111271 A1
(43) Pub. Date: Apr. 30, 2009

(54) ISOTROPIC SILICON ETCH USING ANISOTROPIC ETCHANTS

(75) Inventor: John S. Starzynski, Brooklyn Park, MN (US)

Correspondence Address: HONEYWELL INTERNATIONAL INC., 101 COLUMBIA ROAD, P O BOX 2245, MORRISTOWN, NJ, 07962-2245, US

(73) Assignee: HONEYWELL INTERNATIONAL INC., Morristown, NJ (US)

(21) Appl. No.: 11/925,336

(22) Filed: Oct. 26, 2007

(51) Int. Cl. H01L 21/311

(52) U.S. Cl. 438/701; 257/E21.249

(57) ABSTRACT

Methods for isotropically etching a monocrystalline silicon wafer. An example method includes applying a layer of material at least one of onto a first side or into a first side of the monocrystalline silicon wafer and isotropically etching a non-linear pit into the monocrystalline silicon wafer using an anisotropic etchant. The applied layer of material has a faster etch rate than the monocrystalline silicon wafer.

### BACKGROUND OF THE INVENTION

Etchants that are chemical bases such as Potassium Hydroxide (KOH), Sodium Hydroxide (NaOH), Ethylene-Diamine-Pyrocatechol (EDP), and Tetra-Methyl Ammonium Hydroxide (TMAH) etch the (100) planes of monocrystalline silicon faster than other crystal planes. These etchants etch the (111) planes the slowest. Therefore, these etchants will preferentially etch in the <100> crystallographic direction. The etch rate in the <111> direction is much slower: 20 to 400 times slower (depending on the etchant, concentration and temperature) than in the <100> direction. Employing one of these etchants to etch a masked wafer, patterned with square or rectangular features, will result in the formation of an etch pit with a V-shaped cross section. For this reason these chemicals are called anisotropic etchants. See FIGS. 1A-D.

The motivation shown in the prior art is to use isotropic etchants to isotropically etch and to use anisotropic etchants to anisotropically etch.

### SUMMARY OF THE INVENTION

The present invention provides a method for isotropically etching a monocrystalline silicon wafer. An example method includes applying a layer of material at least one of onto a first side or into a first side of the monocrystalline silicon wafer and isotropically etching a non-linear pit into the monocrystalline silicon wafer using an anisotropic etchant. The applied layer of material has a faster etch rate than the monocrystalline silicon wafer.

In one aspect of the invention, the applied layer of material includes polysilicon, amorphous silicon, or a fast etching material.

In another aspect of the invention, an etch accelerant is applied to the anisotropic etchant. The shape of the etch can be controlled by varying the concentration of etch accelerant during etching.

In still another aspect of the invention, the pit includes a width and depth dimensions that are controlled according to at least one of the applied materials or the composition of the anisotropic etchant.

### BRIEF DESCRIPTION OF THE DRAWINGS

Preferred and alternative embodiments of the present invention are described in detail below with reference to the following drawings:

FIGS. 1A-D illustrate a conventional anisotropic etching process; and

FIGS. 2-5 illustrate a number of embodiments showing isotropic etching performed using anisotropic etchants.

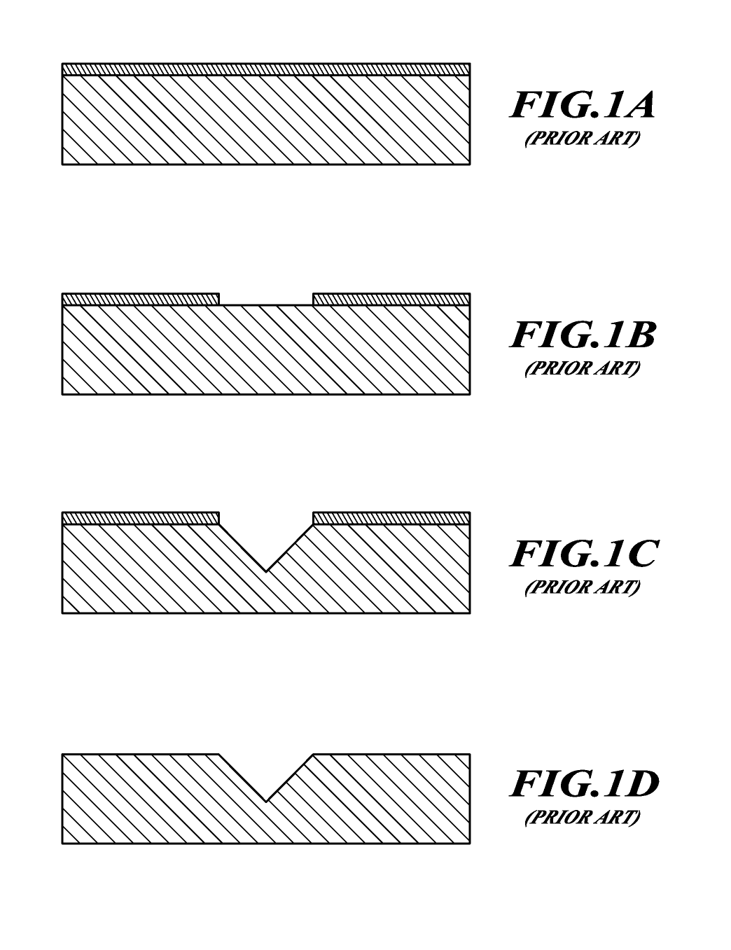

### DETAILED DESCRIPTION OF THE PREFERRED EMBODIMENT

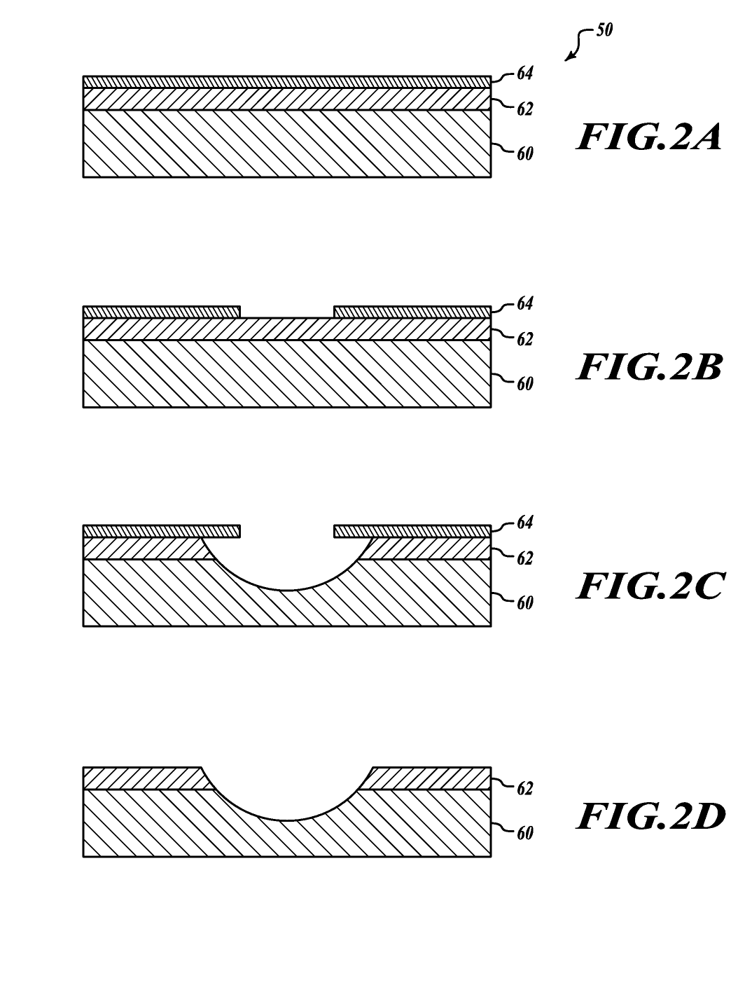

FIGS. 2A-2D illustrates steps in performing an isotropic etch using anisotropic etchants. A monocrystalline silicon wafer 60 has a layer 62 of polysilicon or amorphous silicon deposited on a surface. A hard mask layer 64 is applied over the polysilicon or amorphous silicon layer 62. As shown in FIG. 2B, the hard mask layer 64 is patterned and etched according to a predefined pattern in order to expose a predefined section of the polysilicon or amorphous silicon layer 62.

As shown in FIG. 2C, an anisotropic wet etchant such as hydroxide etchants (e.g., NaOH, KOH) are applied to the surface of the hard mask layer 64 and the polysilicon or amorphous silicon layer 62, thus causing isotropic etching of the polysilicon or amorphous silicon layer 62 and the crystalline silicon wafer 60. The anisotropic etchant etches the polysilicon or amorphous silicon layer 62 faster laterally than the monocrystalline silicon wafer 60. This is because each polysilicon crystal has the slow etching (111) planes randomly oriented with respect to neighboring silicon crystals. Because the (111) planes are randomly oriented they will not impede the lateral etch rate. An amorphous silicon layer 62 lacks the slow etching (111) plane entirely. Thus, a circular shaped pit 70 is produced thereby performing some undercutting of the hard mask layer 64 and producing essentially an isotropic etch pattern. The hard mask layer 64 is then removed. (FIG. 2D). The hard mask layer 64 is patterned and removed using standard photolithography techniques.

The width and depth of the etched circular pit 70 can be controlled by varying the ratio of the width of the hard mask opening to the thickness of the polysilicon or amorphous silicon layer 62.

In another embodiment of the present invention, the polysilicon or amorphous silicon layer 62 has been stressed during deposition on to the monocrystalline silicon wafer 60. Stressing is preformed by controlling deposition rate and temperature. Tensile stress increases the reactivity of the silicon. Stress levels varying from 100 to 1000 Megapascals (MPa) can be easily obtained.

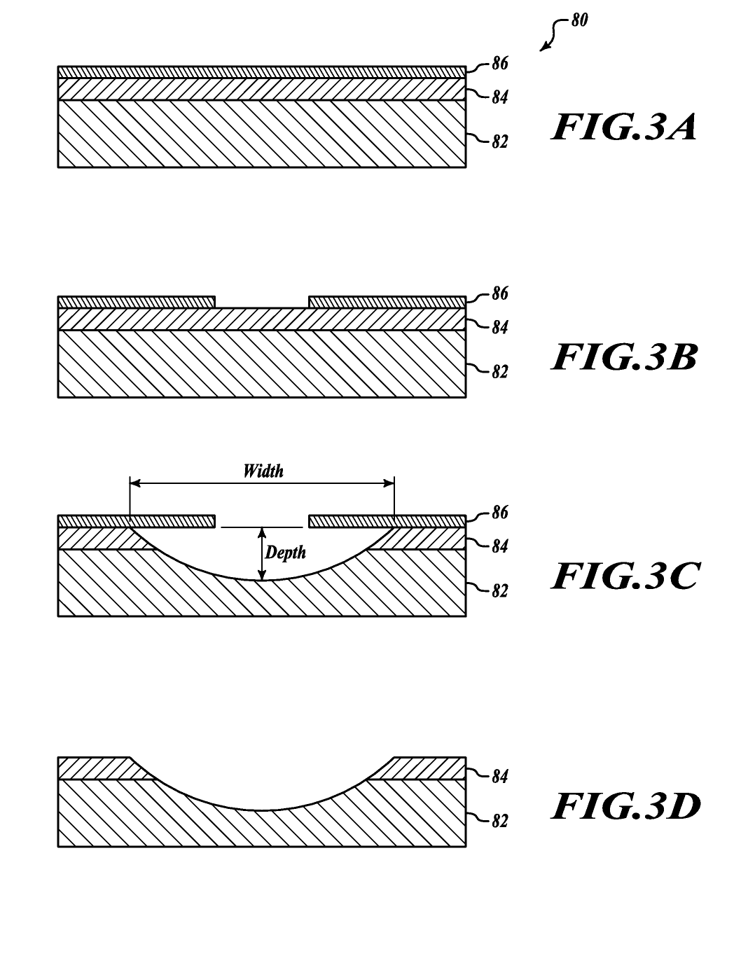

FIGS. 3A-D shows an alternate process for isotropically etching using an anisotropic etchant. A layer of fast etching material 106 is deposited on a monocrystalline silicon wafer 104. The etch rate of the fast etching material can be as low as less than a μm/minute or as high as 400 μm/minute. A hard mask layer 108 is applied over the deposited fast etching layer 106 and is then partially removed in order to expose the desired portion of the fast etching layer 106 similar to FIG. 2B. Next, an anisotropic etchant is applied to the fast etching layer 106 to etch the fast etching layer 106 and the monocrystalline silicon wafer 104 in an isotropic manner, thereby undercutting the hard mask layer 108. The hard mask layer 108 is then removed to fully expose the etched circular pit. Example fast etching materials include silicon dioxide (SiO₂), Ti, and Al. The ratio of the fast etching material etch rate to the silicon etch rate can vary from being as low as 1.1:1 to as high as 400:1.

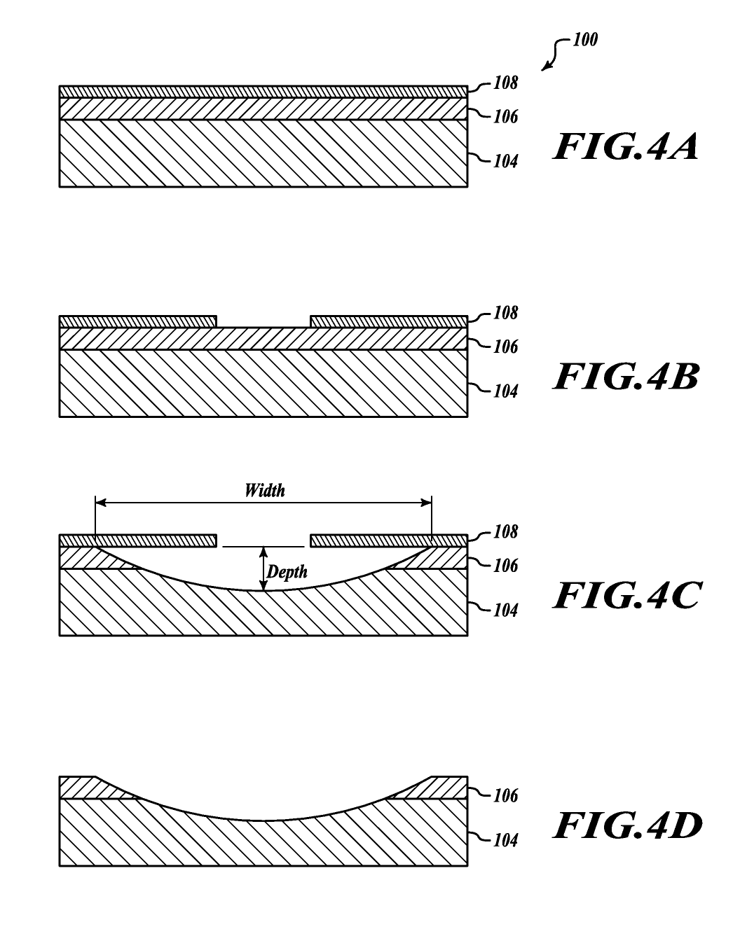

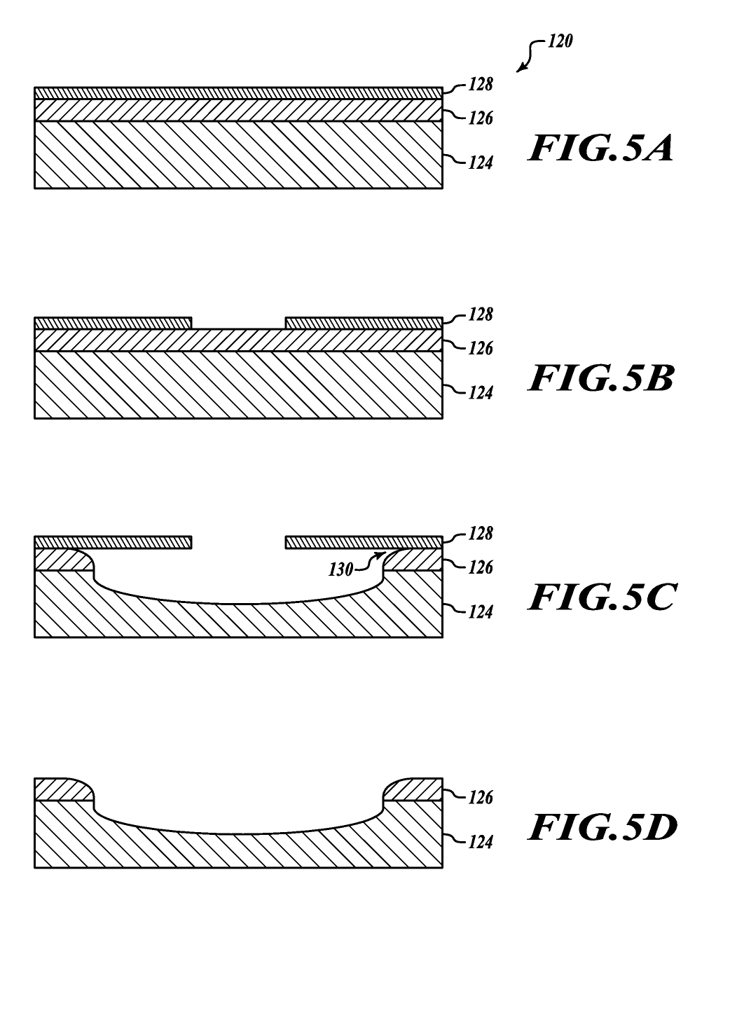

FIGS. 4A-D show a wafer having a monocrystalline silicon wafer 124 with deposited fast-etching layer 126 similar to that as shown in FIGS. 3A-D. However, as shown in FIG. 4C, the layer of fast-etching material 126 and the monocrystalline silicon wafer 124 are etched by a solution that contains an anisotropic etchant and a etch accelerant that will increase the etch rate of the fast etching material. The etch accelerant increases the etch rate ratio of the fast etching material layer 126 and the silicon wafer 124. The result is a pattern (FIGS. 4C and D) whereby the sidewall pattern is S-shaped with heavy undercutting of the fast etching material layer 126 under a hard mask layer 128. The type of geometry that can be accomplished can vary a great deal depending upon the concentration of the etch accelerant and the variation of this concentration during the etching process. Possible etch accelerants include hydrogen peroxide (H₂O₂) and potassium fluoride (KF).

While the preferred embodiment of the invention has been illustrated and described, as noted above, many changes can be made without departing from the spirit and scope of the invention. Accordingly, the scope of the invention is not limited by the disclosure of the preferred embodiment. Instead, the invention should be determined entirely by reference to the claims that follow.

The embodiments of the invention in which an exclusive property or privilege is claimed are defined as follows:

1. A method for isotropically etching a monocrystalline silicon wafer, the method comprising:
applying a layer of material onto a first side or into a first side of the monocrystalline silicon wafer; and
isotropically etching a non-linear pit into the monocrystalline silicon wafer using an anisotropic etchant,
wherein the applied layer of material has a faster etch rate than the monocrystalline silicon wafer.

2. The method of claim 1, wherein the applied layer of material includes polysilicon.

3. The method of claim 2, wherein the width and depth of the etched pit are determined by the thickness of the applied polysilicon.

4. The method of claim 1, wherein the applied layer of material includes amorphous silicon.

5. The method of claim 2, wherein the width and depth of the etched pit are determined by the thickness of the applied amorphous silicon.

6. The method of claim 1, wherein the applied layer of material includes one of a metal, semiconductor, or insulator having an etch rate that is faster than the etch rate of the monocrystalline silicon.

7. The method of claim 6, wherein the width and depth of the etched pit are determined by the etch rate and thickness of the applied layer.

8. The method of claim 6, wherein isotropically etching includes applying an etch accelerant to the anisotropic etchant.

9. The method of claim 8, wherein istropically etching includes varying the concentration of etch accelerant during isotropically etching.

10. The method of claim 1, wherein the pit comprises a width and depth dimension, wherein the width and depth dimension are controlled according to at least one of the applied material or the composition of the anisotropic etchant.
